(19) United States
(12) Patent Application Publication
(10) Pub. No.: US 2008/0100288 A1
(43) Pub. Date: May 1, 2008

(54) Seal inspection apparatus and method

(75) Inventors: Eric Leung, Blackwood, NJ (US); Alexander Skulartz, Atco, NJ (US); Bob Aguero, Delran, NJ (US); Brad K. Menees, Moorestown, NJ (US); Francis Tan, Cherry Hill, NJ (US); Frank J. Harder, Glassboro, NJ (US); John Knapp, Hammonton, NJ (US); Tom Braydich, Mount Laurel, NJ (US)

Correspondence Address: MCDONNELL BOEHNEN HULBERT & BERGHOFF LLP, 300 S. WACKER DRIVE, 32ND FLOOR, CHICAGO, IL, 60606, US

(73) Assignee: Campbell Soup Company, Camden, NJ (US)

(21) Appl. No.: 11/586,390

(22) Filed: Oct. 25, 2006

(51) Int. Cl. G01R 33/14

(52) U.S. Cl. 324/222

(57) ABSTRACT

A seal inspector and a method of inspecting a seal are described. A seal inspector includes an eddy current sensor for detecting changes in an eddy current within a lid seal of a can. The eddy current sensor includes a signal line for creating a magnetic field, which induces the eddy current. The induced eddy current generates a magnetic field that acts on the alternating current and as a consequence produces an eddy current response. A signal processing control unit receives the eddy current response and determines whether a value associated with the eddy current has surpassed a threshold value. If the associated value has surpassed the threshold value, the can may be ejected from a can conveyor system.

### FIELD

The present invention relates generally to an apparatus and method for detecting a seal, and more particularly to an apparatus and method for non-visual verification of a seal between a container and a metallic lid of the container.

### BACKGROUND

During the early Revolutionary Wars, the notable French newspaper Monde, prompted by the government, offered a hefty cash award of 12,000 Francs to any inventor who could come up with a cheap and effective method of preserving large amounts of food. The massive armies of the period required regular supplies of quality food, and so preservation became a necessity. In 1809, the French confectioner Nicolas Frangois Appert developed a method of vacuum-sealing food inside glass jars.

Eventually, glass jars were replaced with cylindrical tin or steel cans. The French Army began experimenting with issuing tinned foods to its soldiers, but the slow process of tinning foods and the even slower development stage prevented the army from shipping large amounts around the Empire, and the war ended before the process could be perfected. Unfortunately for Appert, the factory which he had built with his prize money was burned down in 1814 by Allied soldiers invading France. Following the end of the Napoleonic Wars, the process was gradually put into practice in other European countries and in the United States. Based on Appert's methods of food preservation the packaging of food in sealed airtight tin-plated wrought-iron cans was first patented by an Englishman, Peter Durand, in 1810. Initially, the canning process was slow and labour-intensive, making the tinned food too expensive for ordinary people to buy. However, increasing mechanization of the process, coupled with a huge increase in urban populations across Europe, resulted in a rising demand for tinned food.

Today, the process of tinning may be referred to as “canning” and, in general, the process includes first heating food to a temperature that destroys contaminating microorganisms, and then sealing the food in air-tight container (i.e., a can). Because of the danger of botulism and other pathogens, most foods are canned under conditions of both high heat and pressure, normally at temperatures of 240-250° F. (116-121° C.). Foods that must be pressure canned include most vegetables, meats, seafood, poultry, and dairy products.

### SUMMARY

Although the process of canning has evolved and matured greatly since the early 1800's, the desire to improve the efficiency of the canning process remains. Generally speaking, most canning processes are heavily automated; typically, the more automated a process, the greater the efficiency. However, despite increased efficiency, the importance of maintaining a non-contaminated food produce remains. The integrity of a seal between a can and a can lid must remain intact. If the lid seal is corrupt, food within the can may spoil and create a potentially serious health risk. To verify the integrity of a lid seal, a visual inspection may be performed or other—complicated—inspection steps may be carried out, both of which may reduce the efficiency of an automated canning process.

Therefore, a seal inspector is presented. The presented seal inspector may be used in conjunction with an automated can conveyor system so that when the seal inspector detects a failed lid seal in a can, the seal inspector may indicate that the can should be ejected out of the system. The seal inspector may reduce or eliminate the need for visual inspection of a lid seal. In addition, the seal inspector may be used in lieu of more complicated seam inspection techniques, such as an optical sensor based seal inspector.

By way of example, an example seal inspector is described. The example seal inspector includes an eddy current sensor, which is configured to scan a lid seal of a container. The seal may be located at a metallic lid seal, where the lid seal is used to maintain a vacuum or air-tight seal within the container. The eddy current sensor, in operation, detects when a value associated with an eddy current within the container surpasses a threshold value. When a seal has failed, the associated value of the eddy current surpasses the threshold value and the eddy current sensor responsively outputs a signal indicative of the failed seal.

In an example configuration, the eddy current sensor generates an AC magnetic field. Alternatively, an AC magnetic field may be generated by a magnetic field source. In either case, the AC magnetic field generates an eddy current within the lid seal, and possibly the container. The eddy current sensor may include a signal processing control unit that detects changes in the eddy current, which, for example, may be carried out by detecting a change in a magnetic field or a magnetic force associated with the eddy current. Accordingly, when a value associated with the eddy current surpasses a threshold value, a failed seal is detected. The threshold value, for example, may be stored in the control unit or calculated by the control unit. For instance, if the threshold value is calculated by the control unit, the threshold value may be an average eddy current value calculated by the control unit as the container rotates about an axis. Thus, if the eddy current variation surpasses the average eddy current value, a failed seal exists within the container.

In another example, the seal inspector may include a can receptacle for receiving a can and an eddy current sensor for inspecting a lid seal of the can. The eddy current sensor may include a signal line that is coupled to a signal processing control unit. The signal line may be positioned so that when the control unit generates an alternating current within the signal line, the signal line provides feedback to the control unit. For example, the eddy current will induce a magnetic field that varies as attributes of the lid seal vary; as the induced magnetic field varies, the alternating current will likewise vary. Thus, the alternating current may be used as feedback by the control unit to determine a variation in the induced magnetic field. To scan the entire seal, the can receptacle may be configured to rotate, or, alternatively, the eddy current sensor may be configured to rotate about the can.

The control unit, for example, may include a memory that stores a threshold value. The threshold value may be indicative of a failed lid seal. In addition to the memory, the control unit may also include a processor for executing instructions in the memory, where the instructions direct the processor to compare the threshold value to a value of the alternating current. In one example, the control unit may be configured to calculate an average alternating current value, which is used as the threshold value. The control unit may be further configured to output a seal failure signal when the threshold value is surpassed. The can receptacle may be coupled to a can rejector, which rejects a can out of a can conveyor system when the seal failure signal is induced.

In an alternative example, a method inspecting a seal is described. The method includes inducing an eddy current at a seal of a container and comparing a value of the eddy current to a threshold value, such as an average eddy current density associated with the seal of the container. To induce the eddy current, an eddy current sensor may be provided at the seal of the container and generate an AC magnetic field at the seal. The example method may further include rotating the can or rotating the eddy current sensor, either of which allows the sensor to inspect the entire seal.

These as well as other aspects and advantages will become apparent to those of ordinary skill in the art by reading the following detailed description, with reference where appropriate to the accompanying drawings. Further, it is understood that this summary is merely an example and is not intended to limit the scope of the claims.

### BRIEF DESCRIPTION OF THE DRAWINGS

Certain examples are described below in conjunction with the appended drawing figures, wherein like reference numerals refer to like elements in the various figures, and wherein:

FIG. 1 is an isometric drawing of a seal inspector that is coupled with a can conveyor system, according to an example;

FIGS. 2A-C are isometric drawings of a can that is properly sealed and cans that have a corrupt lid seal, according to an example;

FIGS. 3A-B are isometric drawings of eddy currents that are generated in a corrupt and non-corrupted lid seals, according to an example;

FIG. 4 is a flow diagram of an example method for inspecting a seal or a seam of a container;

FIGS. 5A-B are an isometric drawing of the seal inspector of FIG. 1 and a graph showing an eddy current response of a properly sealed can, according to an example;

FIGS. 6A-B are an isometric drawing of the seal inspector of FIG. 1 and a graph showing an eddy current response of an improperly sealed can, according to an example;

FIG. 7 is an isometric drawing showing an improperly sealed can being ejected from the can conveyor system of FIG. 1, according to an example;

FIGS. 8A-B are an isometric drawing of the seal inspector of FIG. 1 and a graph showing an eddy current response of an improperly sealed can, according to an example; and

FIG. 9 is an isometric drawing of a seal inspector that includes an eddy current sensor that is configured to rotate about a can, according to an example.

### DETAILED DESCRIPTION

a.) Seal Inspector and Can Conveyor System

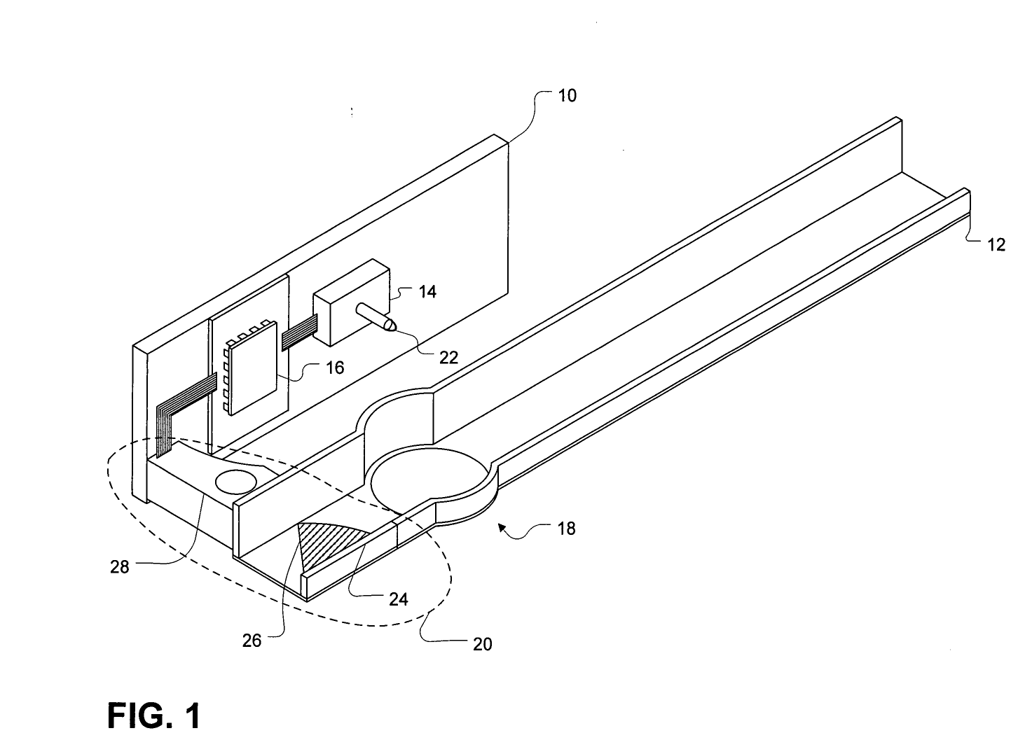

Turning now to the figures, FIG. 1 is an isometric drawing of a seal inspector 10 that is coupled to a can conveyor system 12. The seal inspector 10 includes an eddy current sensor 14 and a signal processing control unit 16. The sensor 14 is electrically coupled to the control unit 16. The eddy current sensor 14 includes a signal line 22, which is electrically coupled to the control unit 16. The control unit 16 may include a processor and a memory (both not shown), where the processor is configured to execute instructions stored in the memory for providing a variety of functions that will be described below.

The can conveyor system 12 includes a can receptacle 18 and a can rejector 20, which is coupled to the control unit 16. The can conveyor system 12 may include a conveyor belt, chain drive, or other type of drive mechanism for moving a plurality of cans from an upstream automated process, through the seal inspector 10, and then to a downstream automated process. It should be understood that the can conveyer system 12 may be a large-scale automated canning system and FIG. 1, for example, may illustrate only a portion of such a large-scale system. For instance, a can may move out of a can sealing process (not shown) and towards the can receptacle 18.

The can receptacle 18 is configured to rotate so that when a can is within the can receptacle 18, the can will rotate about a central axis of the can. In addition, the sensor 14 should be positioned within a sufficient range, so that the sensor 14 may generate an AC magnetic field within a seal or a seam of a can. Further, the sensor 14 should also be positioned so that the sensor 14 may be able to detect a change in the magnitude of an eddy current and/or a change in a magnetic field induced by the eddy current.

The can rejector 20 includes a swing plate 24, a swing arm 26, and a servo 28. The swing arm and plate 24, 26, are configured to be opened and closed by the servo 28. In FIG. 1, the swing arm and plate 24, 26, are in a closed position. When directed to be open, the servo 28 pulls the swing arm and plate 24, 26 in, so that a can may be removed, or ejected, from the can conveyor system 12.

A can may be moved through the can conveyor system 12 towards the can receptacle 18. When a can enters the can receptacle 18, the can will begin to rotate. The sensor 14, for example, may “sense” that a can has entered the can receptacle and may initiate rotation. Alternatively, an optical sensor (not shown) may detect that a can has entered the can receptacle 18, and thus begin to rotate the can. As a can is rotated within the can receptacle 18, the sensor 14 will inspect a seal or a seam of the can (i.e., a lid seal). In particular, the signal line 22 in conjunction with the control unit 16, will measure a change in an induced eddy current (e.g., a change in current, magnetic field, or magnetic force), a process of which will be described in more detail below. If the can passes inspection, the can will continue to move on in the can conveyor system 12. However, if the can fails the inspection, the swing arm and plate 24, 26 will open, and the can will be ejected from the can conveyor 12. To do this, the control unit 16, which is coupled to both the sensor 14 and the servo 28, may determine that the can failed the seal/seam inspection, and should then send a signal to the servo 28, which will cause the can to be ejected.

b.) Corrupt vs. Non-Corrupt Seals/Seams

When inspecting a can, or more generally a container, the sensor 14 may be arranged to detect the integrity of a lid seal. If the lid is not properly sealed to the container, the sensor 14 may detect a change in magnitude or variation in the eddy current, which may be indicative of a failed seal. It should be noted, that where appropriate the term “seal” may be interchanged with the term “seam” and vice versa. The seal inspector may be used at a variety of metallic seals or seams to detect seal/seam corruption. It is contemplated that a seal inspector may be configured to inspect other types of seals, those of which are not necessarily located at a container-body/container-lid seal.

Generally speaking, a seaming tool is used to seam a lid to a container. The seaming tool applies a lid to a container by causing hooks within the container and the lid to overlap or by wrapping a metal band around a container body and a lid. The lid may, additionally or alternatively, be sealed by solder, cement, or a weld. It should be understood that a wide variety of processes may be used to seal a container.

A container may comprise a variety of materials, such as steel, aluminum, tin, or chromium. The materials may further include an alloy (e.g., Cu, MN, MG, Zn, Si, Cr, Fe, Ti, etc.) and be treated by a coating, hot-dipping, or electro-plating. In addition, a container may come in a variety of forms, such as a cylindrical body and two round lids or an extruded cylindrical body and one round lid. The examples described below generally relate to the latter type, and more specifically a can, but it should be understood that additional examples are possible. Furthermore, the body of a cylindrical is not limited to being cylinder or comprised of a metal. For example, the body of a container may comprise a material such as plastic, glass, wood, etc.

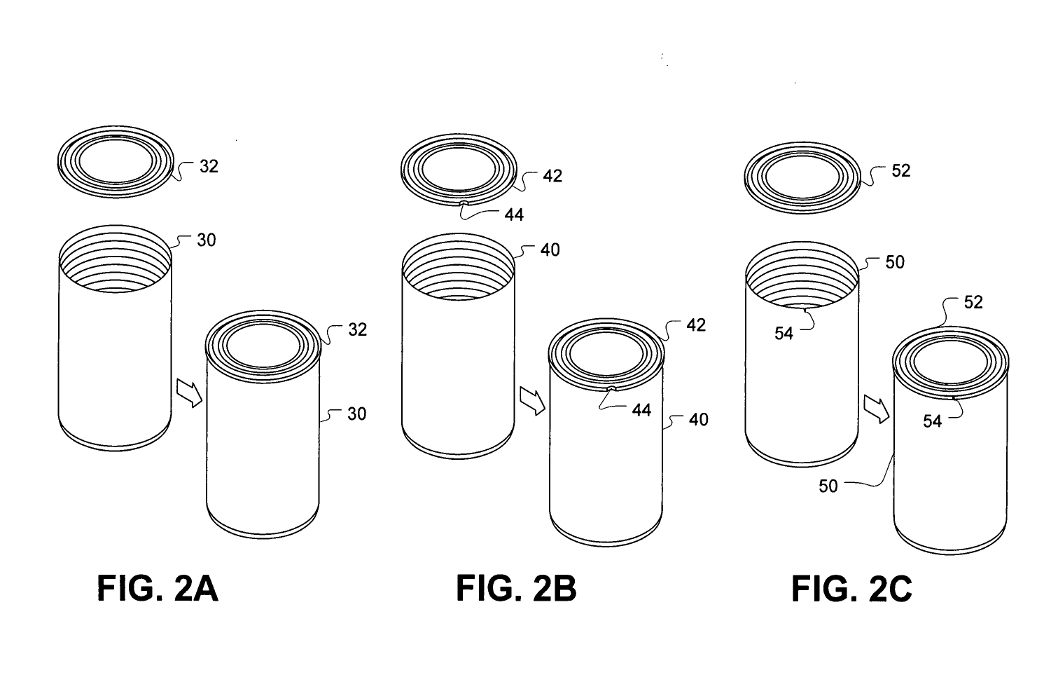

FIG. 2A shows a can 30 before being sealed with a lid 32. After sealing, the sealed can 30 is defect free in that the seal of the lid 32 is not corrupted. Thus, the contents of the can 30 should be adequately protected from the outside environment. FIG. 2B shows a can 40 before being sealed with a lid 42. The lid 42 has a defect 44, which corrupts the seal of the can 40. Similarly, in FIG. 2C, a can 50 is shown before being sealed with a lid 52. The can 50 has a defect 52 which causes corruption of a seal with the lid 52.

The defects shown in each of the cans 40, 50, may take on a variety of forms. In addition, other types of defects such as a dent or other type of deformity are possible. Generally speaking, a failed seal may occur for a variety of reasons. For example, a failed seal may occur during the sealing process of a container or during an automated process. The container, for example, may have a defect which prevents a lid from sealing the container correctly. Alternatively, the container may be physically impacted during automation, thus creating a defect in the seal. Other causes for defects are possible.

c.) Eddy Current Generation

Eddy currents are produced in conductive materials by an alternating or moving magnetic field intersecting a conductor or vice-versa. The relative motion causes a circulating flow of electrons, or current, within the conductor. These circulating eddies of current create electromagnets with magnetic fields that oppose the change in the external magnetic field. The stronger the magnetic field, or greater the electrical conductivity of the conductor, the greater the currents developed and the greater the opposing force.

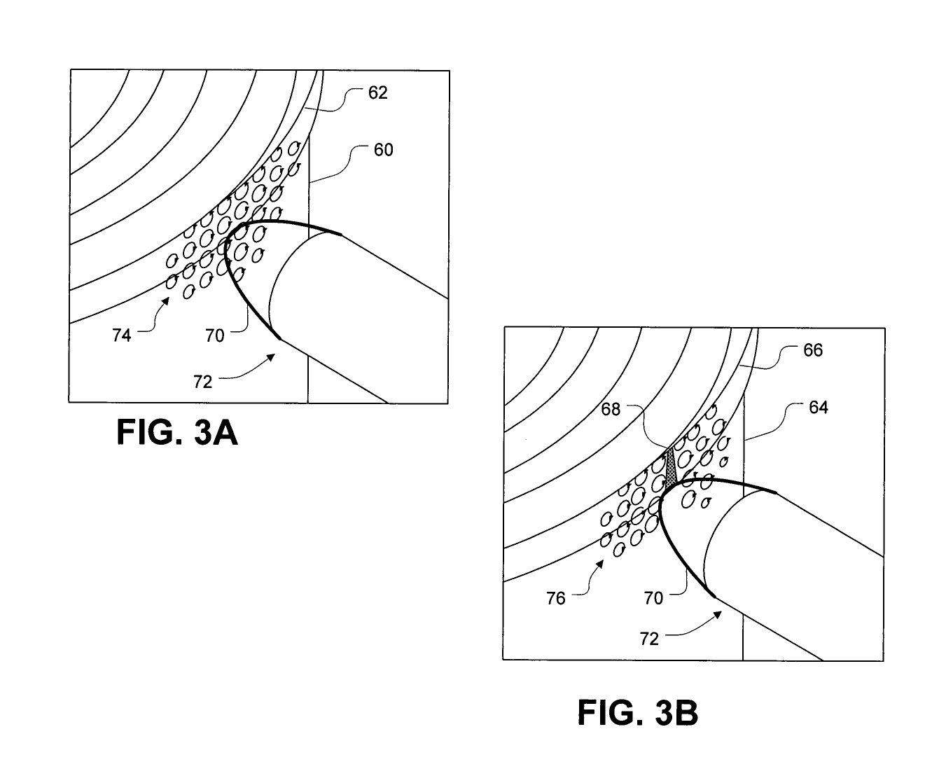

FIGS. 3A-B respectively show eddy current generation in a can 60, which has a defect free lid seal 62, and a can 64, which has a lid seal 66 having a defect 68. In each of the FIGS. 3A-B a signal line 70 of an eddy current sensor 72 is used to generate a magnetic field that creates an eddy current in each of the lid seals 62, 64. The lid seal 62 has an induced eddy current 74 and the lid seal 64 has an induced eddy current 74. The defect 68 causes the eddy current 76 to differ in magnitude relative to the magnitude of the eddy current 74. Depending on the type and/or size of a defect, this eddy current variation may be larger or smaller than a defect-free lid seal. Because the eddy currents 74, 76 have differing magnitudes, the magnetic force that each of the eddy currents 74, 76 generate will also differ. The differing eddy currents, differing magnetic fields, or differing magnetic forces, may then be used to determine if a defect is present in either of the lid seals.

To inspect an entire seal, a can should be rotated so that the eddy current sensor scans the entire circumference of a can. Alternatively, the eddy current sensor may be rotated about a can. Because a can is relatively symmetric about the central axis, the magnitude of the eddy current should not vary if the lid seal is defect free. However, if a defect is present, such as the defect 68, the induced eddy current will deviate in magnitude, the resultant magnetic force will deviate in magnitude, and a failed seal may be detected.

To detect a deviation in eddy current or magnetic force, the eddy current sensor 72 may be coupled to a signal processing control unit (not shown) that generates an alternating current in the signal line 74. When the magnetic field acts on the alternating current, the control unit will need to either increase or decrease the power needed to drive the alternating current. For example, if the control unit needs more power, the magnitude of an eddy current may have increased. Alternatively, if the control unit needs less power, the magnitude of an eddy current may have decreased. Such feedback serves as a relative indicator as to the magnitude of the eddy current.

It should be noted that a lot of factors may influence an eddy current, or more specifically the resultant magnetic field generated by the eddy current. For example, the density of an eddy current is a function of a variety of factors, including the frequency of the applied magnetic field. The higher the frequency is, the denser the eddy current at the surface of a conductor. The magnitude of the alternating current may need tailored to the type of can or seal that is being inspected. For instance, if a plastic can having a metallic lid is to be inspected, the eddy current response will be different than a metallic can having a metallic lid.

d.) Method of Inspecting a Seal

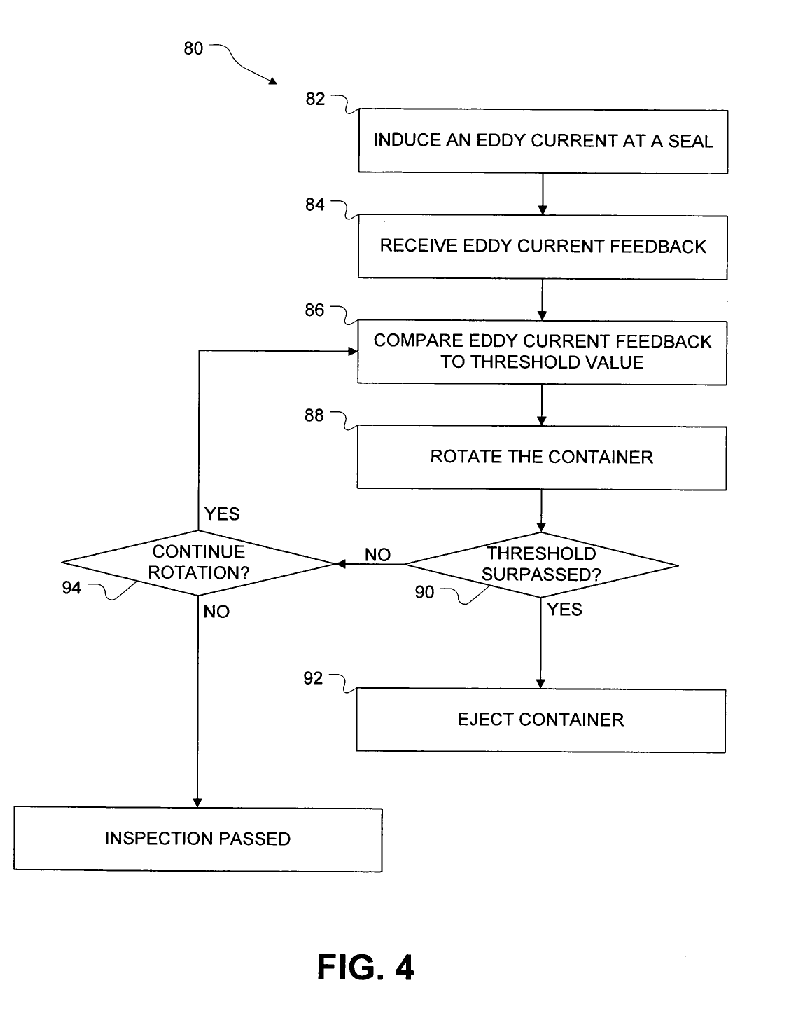

FIG. 4 shows a method 80 for inspecting a lid seal using an eddy current sensor. At block 82, an eddy current is induced at a seal of a container. This may be carried out via a signal line coupled to a signal processing control unit (described with reference to FIGS. 3A-B). Alternatively, an AC magnetic field source may be used to generate an eddy current. At block 84, feedback from the eddy current may be received by a control unit. The feedback may be a change in magnitude of an eddy current, a magnetic field induced by the eddy current, or a magnetic force induced by the eddy current.

At block 86, a value associated with the eddy current is compared to a threshold value. The threshold value may comprise one or more values and may be determined in various ways. For example, the threshold value may be a value that is stored in a memory of the control unit. In addition, the threshold value may be determined by the type of container being inspected. For example, an aluminum can and a tin can may have different stored thresholds. Accordingly, the threshold value may be changed if the seal inspector inspects a different type of container.

Alternatively, the threshold value may be calculated using the eddy current feedback from the block 84. As the container is rotated, the control unit may calculate a real-time threshold value. If, at any point, the eddy current feedback deviates from the threshold value, the container may be subsequently rejected from a conveyor system (see the description relating to blocks 90 and 92). Block 88 includes the container being rotated; however, as described above, the eddy current sensor may alternatively be rotated about a container.

At decision block 90, the control unit determines whether the threshold has been surpassed (e.g., the eddy current feedback has dipped below or exceeded a threshold value). If the container has surpassed the threshold value, the container is ejected from a conveyor system, shown at block 92. At decision block 94, the container has not surpassed the threshold value, and the container (or the eddy current sensor) may either continue to be rotated or, if the container has been fully inspected, the container may have passed seal inspection.

It should be noted that the method 80 should not be viewed as limiting. Certain blocks may be added or omitted without changing the scope of eddy current seal inspection. For example, the decision block 90 may not be carried out until a container has been completely rotated. Furthermore, the container (or eddy current sensor) may be rotated more than one time.

e.) Example Pass/Fail Scenarios

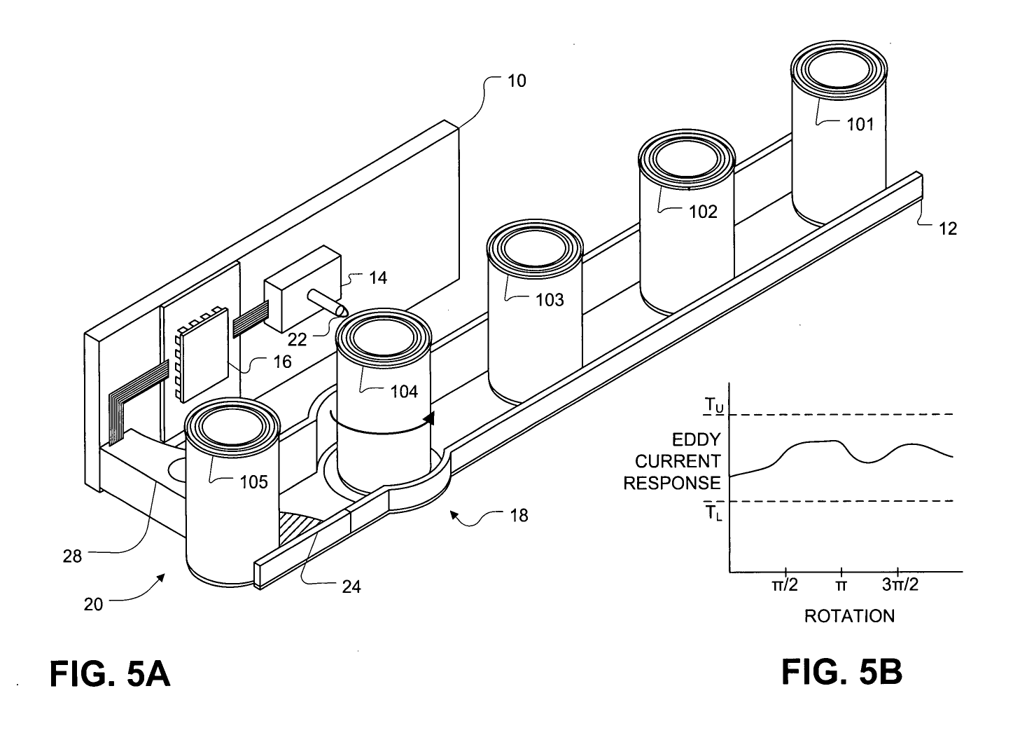

To illustrate an application of the method 80, FIGS. 5A-B show the seal inspector 10 and the can conveyor system 12; where the can conveyor system 12 is moving upstream cans 101-103 towards the can receptacle 18; the can receptacle is rotating a can 104 and the seal inspector 10 is inspecting the can 104; and, the downstream can 105 is moving away from the can receptacle 18 (i.e., after passing seal inspection). The cans 101 and 103-105 are defect free. The can 102, on the other hand, has a defect 110. As described above the defect 110 may corrupt a lid seal of the can 102, and thus corrupt the food contents of the can 102. The seal inspector 10 is used in conjunction with the can rejector 20, to keep the defect free cans in the can conveyor system 12, and remove cans that are not relatively defect free.

As FIG. 5A shows, the seal inspector 10 is inspecting a lid seal of the can 104. The eddy current sensor 14, and more particularly the signal line 22, is arranged so that as the can 104 rotates, the signal line 22 carries an alternating current that induces an AC magnetic field. The AC magnetic field creates an eddy current in the lid seal of the can 104. In additional example, and depending on the type of can (i.e., metallic or non-metallic) that is being inspected, an eddy current may also be induced in the body of the can 104. In general, where the eddy current is induced may depend on the type of can, or the type of seal being used. In some example, an outer circumference of the lid seal may have an induced eddy current. In an alternative example, a portion of a can and a portion of the lid seal may both have an induced eddy current.

As the can 104 is rotated, the induced eddy current creates a magnetic field which acts on the alternating current in the signal line 22. The control unit 16 monitors variations in the alternating current and accordingly detects whether these variations surpass a threshold value. FIG. 5B shows a graph of an eddy current response of the can 104 as it is rotated. The eddy current response may comprise a variety of signal types, such as a current, voltage, or power, and may vary based on the type of configuration of the control unit 16. FIG. 5B shows that the eddy current response does not surpass either of two thresholds: an upper threshold, T_{U}, and a lower threshold, T_{L}. Therefore, after seal inspection, the can 104 may continue downstream.

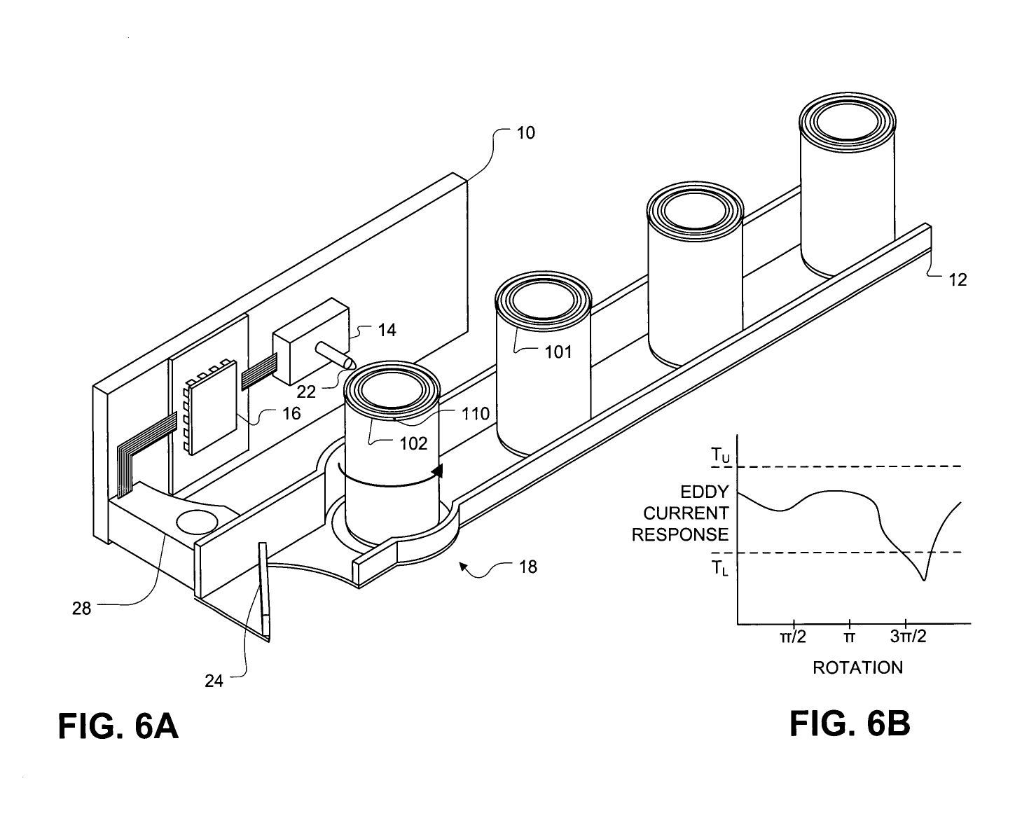

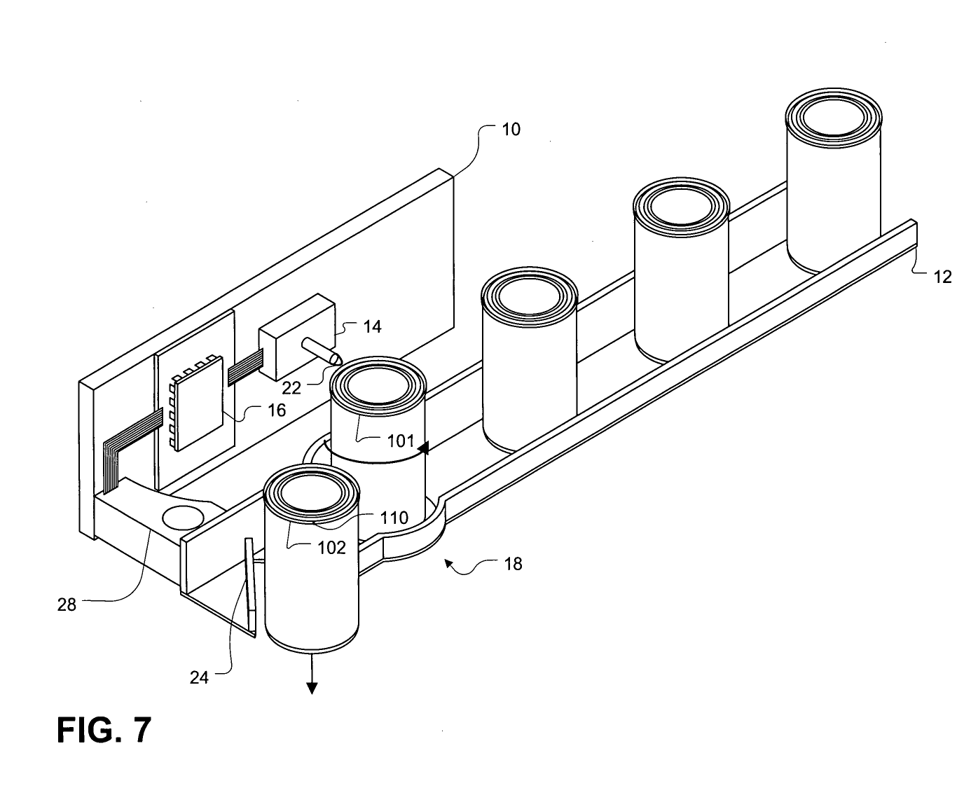

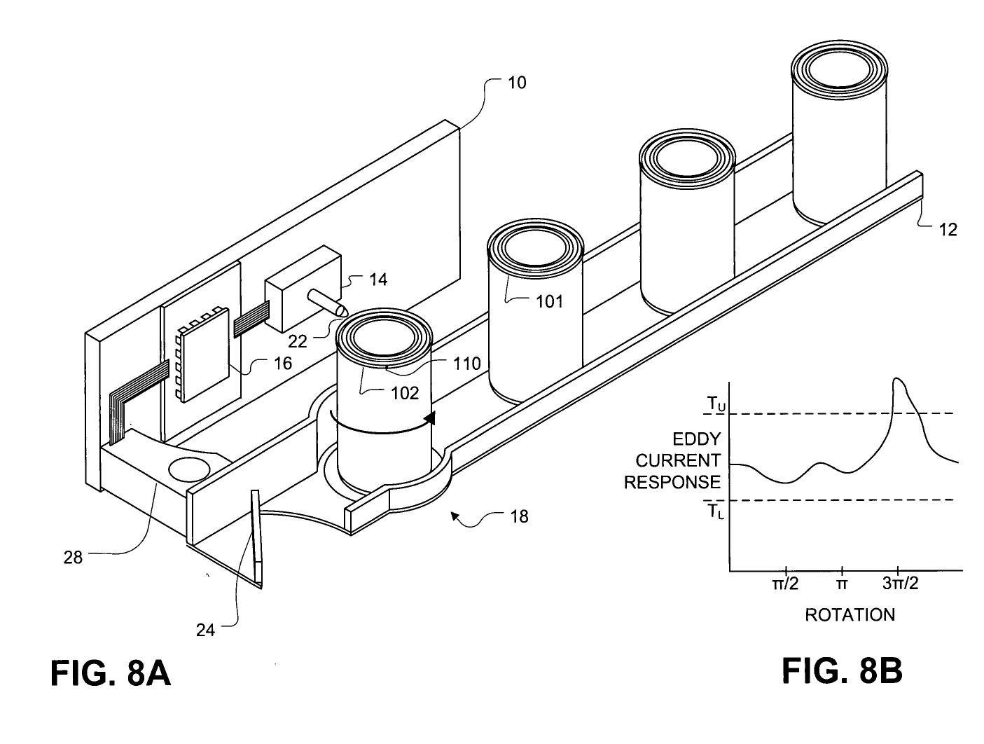

In FIG. 6A, the can 102 has moved into the can receptacle 18, is rotated, and inspected. In FIG. 6B, the defect 110 causes the eddy current response to dip below the lower threshold T_{L}. When this occurs, the control unit 16 triggers the swing plate (shown retracted) and the swing arm 24 to open. When the can conveyor system 12 moves the can 102 forward, the can 102 will be removed or ejected. FIG. 7 shows the can 102 ejected from the can conveyor system 12. FIGS. 8A and 8B show an alternate scenario, where the defect 110 causes the eddy current response to rise above the upper threshold T_{U}.

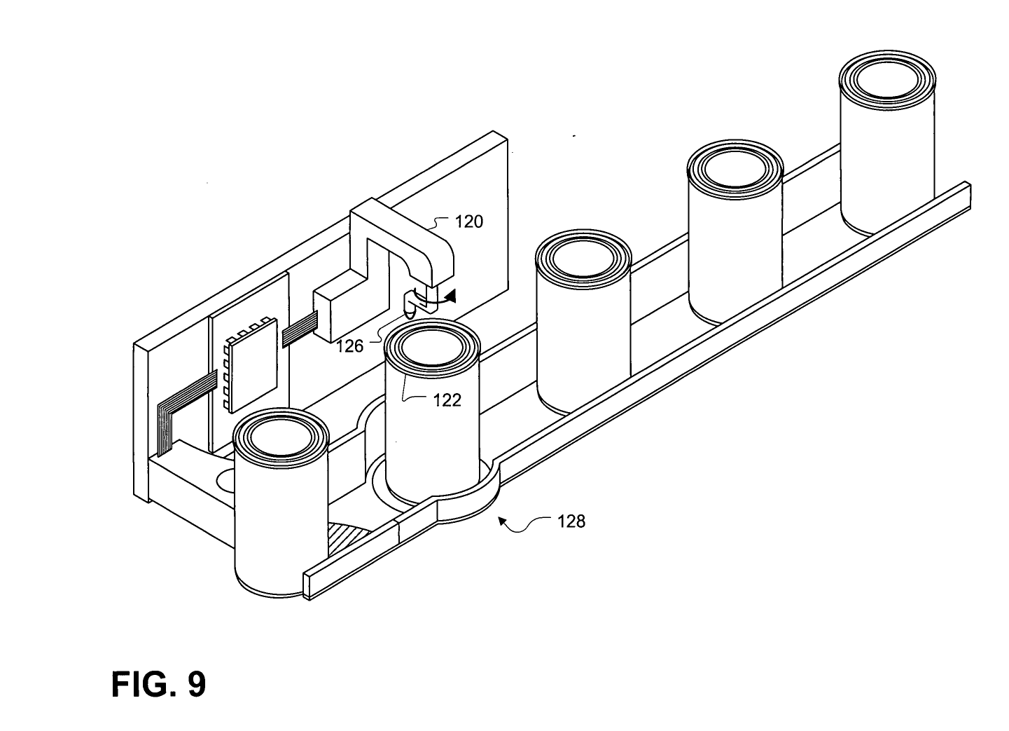

In FIG. 9, an alternative configuration of an eddy current sensor 120 is shown. The sensor 120 is configured to rotate about a central axis of a can 122. The sensor 120 may include similar components as the eddy current sensor 40, such as a signal line 126. However, the sensor 120 also includes a servo, or some other type of mechanical device, which may be used to rotate the sensor 120. In addition, the can receptacle 128 may be configured to rotate, or the receptacle 128 may be stationary.

f.) Conclusion

A variety of examples have been described above. More generally, those skilled in the art will understand that changes and modifications may be made to these examples without departing from the true scope and spirit of the present invention, which is defined by the claims. Thus, for example, the seal inspectors shown in FIGS. 1 and 9 may comprise a variety of structures and are not limited to including only the illustrated elements and the naming or labeling of the elements should not be viewed limiting. A seal inspector may include one or more eddy current sensors that are configured to inspect one or more seals or seams, which may not necessarily comprise a lid seal. Also, an AC magnetic field, although described as being generated by a signal line, may also be generated by another magnetic field source, such as a magnet. Furthermore, the types of signals received and generated by the control unit received may be quite varied. Such signaling may be analog, digital, filtered, unfiltered, current, and/or voltage based, for example. The signaling ranges may also be varied.

It should also be understood that the terms “seal” and “seam” and the terms “can” and “container,” where appropriate, may be used interchangeably. In addition, the described cans or containers are not limited to only being sealed for food storage, the contents of such a can or container may vary depending on the type of product that is being stored. Thus, the described seal inspector may be used in a variety of applications.

Accordingly, the description of the present invention is to be construed as illustrative only and is for the purpose of teaching those skilled in the art the best mode of carrying out the invention. The details may be varied substantially without departing from the spirit of the invention, and the exclusive use of all modifications which are within the scope of the appended claims is reserved.

We claim:

1. A seal inspector, comprising an eddy current sensor configured to scan a seal of a container by using an eddy current within the seal as feedback, wherein when a value associated with the eddy current surpasses a threshold value, the eddy current sensor outputs a signal indicative of a failed seal.

2. The seal inspector as in claim 1, wherein the eddy current sensor is configured to generate an AC magnetic field for creating the eddy current.

3. The seal inspector as in claim 2, wherein the eddy current sensor comprises a signal processing control unit for detecting a change in the eddy current.

4. The seal inspector as in claim 3, wherein the threshold value comprises at least one of a data value stored in the control unit and an average force value, wherein the average force value is calculated by the control unit.

5. The seal inspector as in claim 3, wherein the change in the eddy current is determined by detecting a change in a magnetic force associated with the eddy current.

6. The seal inspector as in claim 1, wherein the failed seal is associated with a lid seal.

7. A seal inspector, comprising:
a can receptacle for receiving a can that is to be inspected; and
an eddy current sensor positioned adjacent to the can receptacle, comprising:
a signal line; and
a signal processing control unit coupled to the signal line for generating an alternating
current within the signal line and for calculating a variation in the alternating current.

8. The seal inspector as in claim 7, wherein the can receptacle is configured to rotate so that the eddy current sensor rotates about the can.

9. The seal inspector as in claim 7, wherein the eddy current sensor is configured to rotate about the can.

10. The seal inspector as in claim 7, wherein the eddy current sensor is further positioned to detect a change in eddy current magnitude at a seal of the can.

11. The seal inspector as in claim 10, wherein the control unit comprises:
a memory for storing a threshold value indicative of a failed lid seal; and
a processor for executing instructions stored in the memory for comparing a value associated with the alternating current to the threshold value.

12. The seal inspector as in claim 11, wherein the processor is further configured to calculate an average value associated with the alternating current value and store the average value as the threshold value.

13. The seal inspector as in claim 11, wherein the processor is configured to output a seal failure signal when the value associated with the alternating current surpasses the threshold value.

14. The seal inspector as in claim 13, wherein the can receptacle is coupled to a can rejector for rejecting a can that induces the seal failure signal.

15. The seal inspector as in claim 14, wherein the can receptacle is coupled to a can conveyor system, and wherein the can rejector is configured to eject the can that induces the seal failure signal away from the can conveyor system.

16. A method of inspecting a seal, the method comprising:
inducing an eddy current at a seal of a container; and
comparing a value associated with the eddy current to a threshold value.

17. The method as in claim 16, wherein inducing an eddy current comprises:
providing an eddy current sensor adjacent to the seal; and
generating an AC magnetic field that induces the eddy current.

18. The method as in claim 17, further comprising performing at least one of rotating the container and rotating the eddy current sensor about the can.

19. The method as in claim 16, wherein the threshold value comprises an average eddy current density associated with the seal of the container.

20. The method as in claim 16, wherein the container comprises a can and the seal comprises a lid seal.
